(19) United States
(12) Patent Application Publication
(10) Pub. No.: US 2024/0113222 A1
(43) Pub. Date: Apr. 4, 2024

(54) THRESHOLD VOLTAGE MODULATION FOR THIN FILM TRANSISTORS

(71) Applicant: Taiwan Semiconductor Manufacturing Company, Ltd., Hsinchu (TW)

(72) Inventors: Yan-Yi Chen, Taipei City (TW); Wu-Wei Tsai, Taoyuan City (TW); Yu-Ming Hsiang, New Taipei City (TW); Hai-Ching Chen, Hsinchu City (TW); Yu-Ming Lin, Hsinchu City (TW); Chung-Te Lin, Tainan City (TW)

(21) Appl. No.: 18/149,312

(22) Filed: Jan. 3, 2023

Related U.S. Application Data
(60) Provisional application No. 63/411,761, filed on Sep. 30, 2022.

(51) Int. Cl. H01L 29/786; H01L 27/07; H01L 29/66

(52) U.S. Cl. CPC H01L 29/78603; H01L 27/0705; H01L 29/66742

(57) ABSTRACT

Some embodiments relate to a thin film transistor comprising an active layer over a substrate. An insulator is stacked with the active layer. A gate electrode structure is stacked with the insulator and includes a gate material layer having a first work function and a first interfacial layer. The first interfacial layer is directly between the insulator and the gate material layer, wherein the gate electrode structure has a second work function that is different from the first work function.

### REFERENCE TO RELATED APPLICATION

This Application claims the benefit of U.S. Provisional Application No. 63/411,761, filed on Sep. 30, 2022, the contents of which are hereby incorporated by reference in their entirety.

### BACKGROUND

As technology advances at a rapid pace, engineers work to make devices smaller, yet more complex to improve and develop electronic devices that are more efficient, more reliable, and have more capabilities. One way to achieve these goals is by improving the design of transistors, as electronic devices comprise a plethora of transistors that together, carry out the function of the device. Overall electronic device performance may benefit from transistors that, for example, are smaller, consume less power, and have faster switching speeds.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a bottom gate (BG) thin film transistor device including an interfacial layer, according to the present disclosure.

FIG. 2 illustrates a cross-sectional view of some embodiments of a top gate (TG) thin film transistor device including an interfacial layer, according to the present disclosure.

FIGS. 3A, 3B, 3C, 3D and 3E illustrate cross-sectional views of some embodiments of a thin film transistor and top gate (TG) thin film transistor device including an interfacial layer, according to the present disclosure.

FIGS. 4 through 10 illustrate cross-sectional views of some embodiments of a method of forming a BG thin film transistor device including an interfacial layer, according to the present disclosure.

FIGS. 11 through 17 illustrate cross-sectional views of some embodiments of a method of forming a BG thin film transistor device including an interfacial layer with a treated surface, according to the present disclosure.

FIGS. 18 through 25 illustrate cross-sectional views of some embodiments of a method of forming a BG thin film transistor device including a first interfacial layer and a second interfacial layer, according to the present disclosure.

FIG. 26 illustrates a methodology in flowchart format that illustrates some embodiments of a method of forming a BG thin film transistor device including an interfacial layer according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Thin film transistors include a gate material layer arranged between two source/drain structures. Depending on the voltage applied to the gate material layer, the thin film transistor may be in an “on” state, where a conductive path is disposed in an active region between the source/drain structures. A threshold voltage is the point where the gate voltage will cause the thin film transistor to be in the “on” state. For example, if the threshold voltage of a thin film transistor is 0.6 volts, a voltage applied at the gate material layer at or above 0.6 volts will cause a conductive path to be formed in the active region between the source/drain structures, allowing current to flow between the source/drain structures. The threshold voltage may be tuned during fabrication of the thin film transistor by implanting ions in the active region.

Where thin film transistors differ from other designs is that their active region is disposed on an active layer that is separate from a substrate and has a significantly lower thickness than the substrate. For example, the active layer of the thin film transistor is thinner than the substrate comprising an active region for other transistors, such as planar metal-oxide semiconductor field effect transistors (MOSFETs). This low thickness supports the operation of the thin film transistors at full depletion. A thin film transistor operating at full depletion has lower leakage and junction capacitance, thereby improving the overall performance of the thin film transistor. Further, in some instances, the active layer may comprise a transparent material (e.g., indium zinc oxide, indium gallium oxide, indium gallium zinc oxide, etc.), where the transparent material and the lower thickness facilitates the thin film transistor being used in optical applications such as for liquid-crystal displays.

When ion implantation is used to tune the threshold voltage of a thin film transistor, the concentration of dopants implanted in the active region of the device is altered. The concentration of dopants may change over time and use, however, due to diffusion out of the active region or the movement of charges throughout the device. The reduction of dopants is known as ion degradation, and may lead to poor performance and a change in threshold voltage in the thin film transistor. Additionally, in the case of thin film transistors, doping may be destructive due to the size (e.g., the lower thickness) of the active layer in use. Ion implantation may cause enough damage to severely limit the range of threshold voltages that are available in thin film transistors.

In some embodiments of the present disclosure, to reduce the effects of ion degradation and to extend the range of threshold voltages available in the thin film transistor, a thin film transistor comprising an interfacial layer is presented. The interfacial layer is part of a gate electrode structure and is disposed between the gate material layer and the active layer. The interfacial layer alters a work function of the gate electrode structure, which tunes the threshold voltage of the thin film transistor. Tuning the threshold voltage by the interfacial layer mitigates or eliminates the implantation of dopants in the active layer, thereby mitigating damage to the thin film transistor and increasing an overall performance of the thin film transistor.

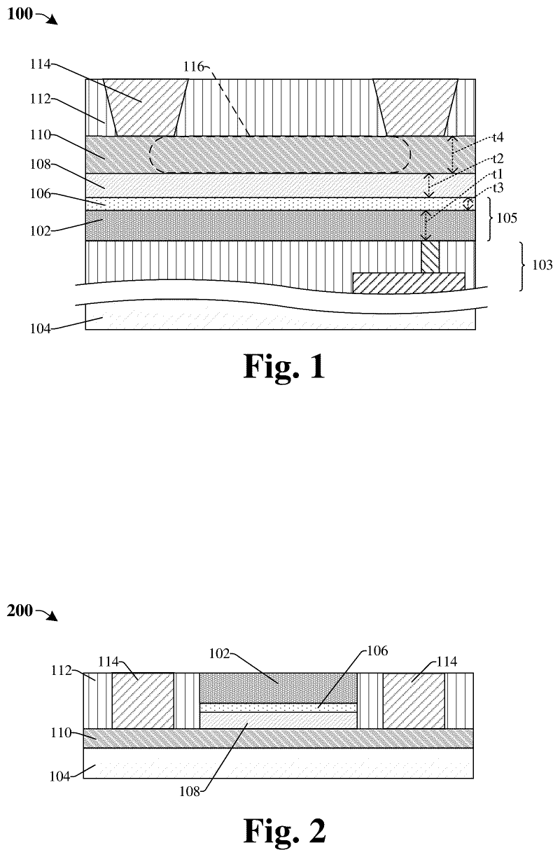

FIG. 1 illustrates a cross-sectional view 100 of some embodiments of a bottom gate (BG) thin film transistor device including an interfacial layer, according to the present disclosure.

As shown in the cross-sectional view 100 of FIG. 1, a gate material layer 102 is provided above a substrate 104. In some embodiments, the gate material layer 102 is directly above and contacting the substrate 104. In other embodiments, as will be seen hereafter, the gate material layer 102 is separated from the substrate 104 by an interconnect structure 103. In some embodiments, the gate material layer 102 has a thickness t1 between approximately 10 nanometers and 100 nanometers, between approximately 1 nanometer and 50 nanometers, or the like. In some embodiments, the gate material layer 102 may comprise one of copper (Cu), tungsten (W), aluminum (Al), titanium (Ti), tantalum (Ta), or some other suitable conductive material. The gate material layer 102 is electrically conductive and has a first work function. The first work function of the gate material layer corresponds to the material chosen: approximately 4.53-5.10 eV for copper, 4.32-5.22 eV for tungsten, 4.06-4.26 eV for aluminum, 4.33 eV for titanium, 4.00-4.80 eV for tantalum, with variance due to the difference in work function for each crystal face of a sample.

An insulator 108 is above a first interfacial layer 106, spacing the first interfacial layer 106 from an active layer 110 of the device. The insulator 108 effectively mitigates charges from flowing between the gate material layer 102 and the active layer 110. In some embodiments, the insulator 108 has a thickness t2 between approximately 5 nanometers and 150 nanometers, between approximately 3 nanometers and 100 nanometers, between approximately 10 nanometers and 200 nanometers, or the like. The insulator 108 comprises an oxide, such as SiO₂, SrO, HfO₂, or the like with a first oxygen areal density. Oxygen areal density refers to the mass of oxygen atoms in the layer over a unit area of the layer.

The first interfacial layer 106 is between the gate material layer 102 and the insulator 108, with the gate material layer 102 and the first interfacial layer 106 defining a gate electrode structure 105. In some embodiments, the first interfacial layer 106 has a thickness t3 between approximately 1 angstroms and 10 angstroms, between approximately 0.5 angstroms 5 angstroms, between 6 angstroms and 15 angstroms, or the like. The first interfacial layer 106 has a second oxygen areal density that is different from the first oxygen areal density of the insulator 108. The difference between the first oxygen areal density and the second oxygen areal density at an interface between the first interfacial layer 106 and the insulator 108 forms a dipole with a direction depending on the magnitude of the first oxygen areal density and the second oxygen areal density. The dipole alters the work function of the gate electrode structure 105. For example, a dipole formed due to the first interfacial layer 106 having a higher areal density than the insulator 108 will cause an increase in the work function of the gate electrode structure 105. Likewise, a dipole formed due to the first interfacial layer 106 having a lower areal density than the insulator 108 will cause a decrease in the work function of the gate electrode structure 105. In some embodiments, the first interfacial layer 106 may comprise one of zinc oxide (ZnO), aluminum oxide (Al₂O₃), indium oxide (In₂O₃), hafnium oxide (HfO), zirconium oxide (ZrO), gallium oxide (GaO), lanthanum oxide (La₂O₃), silicon dioxide (SiO₂), yttrium oxide (Y₂O₃), tantalum oxide (Ta₂O₅).

In some embodiments, due to the thickness t3 of the first interfacial layer 106 being in the range of angstroms, the work function of the gate electrode structure 105 is dependent on both the gate material layer 102 and the first interfacial layer 106. The change in the work function of the gate electrode structure 105 depends on a plurality of factors, comprising the thickness t3, crystalline structure, and material of the first interfacial layer 106, and the dipole moment between the first interfacial layer 106 and the insulator 108. Depending on the materials of the gate material layer 102, the first interfacial layer 106, and the insulator 108 that are chosen, the gate electrode structure 105 may exhibit a work function that is less than or greater than the first work function of the gate material layer 102. In some embodiments, the change in work function from the gate material layer 102 to the work function of the gate electrode structure 105 is between approximately ±10%. For example, if polycrystalline tungsten is the material of choice for the gate material layer 102, the work function of the gate material layer 102 would be approximately 4.55 eV. If the first interfacial layer 106 is made of zinc oxide (ZnO) and the insulator 108 is made of silicon oxide (SiO₂), the work function of the gate electrode structure 105 will increase relative to the work function of the gate material layer 102. In this example, the thickness t3, t2 of the first interfacial layer 106 and the insulator 108 can be chosen such that the resultant work function of the gate electrode structure 105 is 5 eV (approximately 10% higher than the work function of the gate material layer 102). A greater or lesser variance from the work function of the gate material layer 102 can be achieved by altering the thickness t3, t2 and materials of the first interfacial layer 106 and the insulator 108.

The active layer 110 is spaced from the first interfacial layer 106 by the insulator 108. In some embodiments, the active layer 110 has a thickness t4 less than the thickness t1 of the gate material layer 102. The active layer 110 comprises one of silicon (Si), polysilicon (poly-Si) or a metal oxide film such as indium zinc oxide (IZO); indium gallium oxide (IGO); indium gallium zinc oxide (IGZO); indium tungsten oxide (IWO); or indium tungsten zinc oxide (IWZO). In some embodiments, the active layer 110 is an intrinsic semiconductor. In other embodiments, the active layer 110 is substantially free of dopants, with a dopant concentration of less than 10¹⁰ atoms/cm³.

Source/drain structures 114 overlie the active layer 110 on opposite ends of the active layer 110. Between the source/drain structures 114 within the active layer 110 is the active region 116 of the thin film transistor. The source/drain structures 114 are surrounded by a dielectric layer 112 which extends over and around the active layer 110, insulator 108, first interfacial layer 106, and gate material layer 102.

By altering the work function and threshold voltage of the device through including a first interfacial layer 106 in the gate electrode structure 105, doping of the active region 116 may be reduced. For example, the implantation of dopants in the active region 116 to achieve a target threshold voltage may be eliminated or reduced. This prevents or mitigates the effects of ion degradation on the threshold voltage and damage caused to the crystal lattice of the active layer 110 caused by the doping of the active region 116. Thus, an overall performance of the thin film transistor is increased.

FIG. 2 illustrates a cross-sectional view of some embodiments of a top gate (TG) thin film transistor device including an interfacial layer, according to the present disclosure.

As shown in the cross-sectional view 200 of FIG. 2, in some embodiments, the thin film transistor may be a TG device. In the TG device of FIG. 2, the active layer 110 is directly over and contacting the substrate 104. The source/drain structures 114 are overlying the active layer 110, and surrounded by the insulator 108. The insulator 108 spaces the active layer 110 and the source/drain structures 114 from the first interfacial layer 106. The first interfacial layer 106 overlies the insulator 108. In some embodiments, the first interfacial layer 106 extends past outer sidewalls of the source/drain structures 114 and to outer sidewalls of the insulator. In other embodiments, the first interfacial layer 106 is confined beneath the gate material layer 102 that is centered between the source/drain structures 114 (not shown).

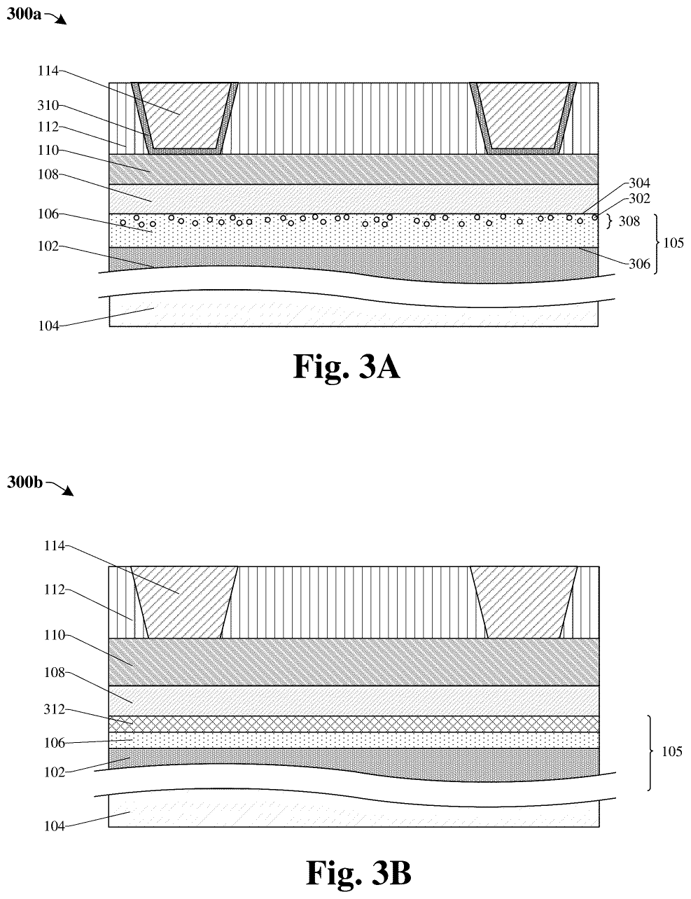

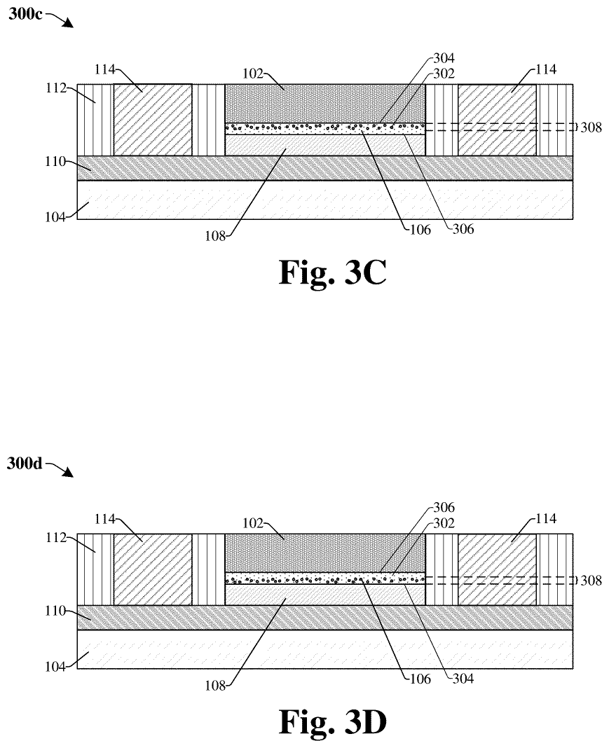

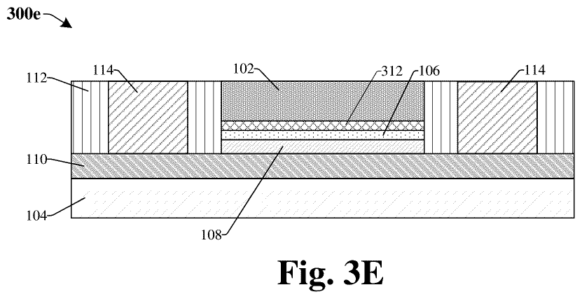

FIGS. 3A, 3B, 3C, 3D and 3E illustrate cross-sectional views of some embodiments of a thin film transistor and top gate (TG) thin film transistor device including an interfacial layer, according to the present disclosure.

As shown in the cross-sectional view 300a of FIG. 3A, the thin film transistor may have a doped region 308 within the first interfacial layer 106. In some embodiments, the doped region 308 is the result of a surface treatment process where dopants 302 are implanted near a first surface 304 of the first interfacial layer 106. In some embodiments, the dopants 302 are hydrogen, oxygen, nitrogen, a combination of hydrogen and oxygen, or the like. In some embodiments, the doped region 308 is just beneath a first surface 304 of the first interfacial layer 106 and does not extend to a second surface 306 of the first interfacial layer 106 opposite the first surface 304. In some embodiments, the first interfacial layer 106 is not formed and the surface treatment process may be applied to the gate material layer 102, defining a doped interfacial layer (not shown). In other embodiments, the dopants 302 are distributed in a gradient with a highest concentration of dopants at or near the first surface 304 and a lowest concentration of dopants at or near the second surface 306. The distribution of the dopants 302 can be altered by the temperature of the chamber the surface treatment is performed in, the amount of time the first interfacial layer 106 is exposed to the surface treatment, the pressurization of the chamber the surface treatment is performed in, the type of dopants being introduced in the surface treatment, the energy of the plasma in the surface treatment, and the direction the surface treatment is being applied to the interfacial layer (e.g., the incident angle).

Depending on the materials of the gate material layer 102, the first interfacial layer 106, and the dopants 302 that are chosen, the gate electrode structure 105 may exhibit a work function that is less than or greater than the work function of a nearly identical but undoped gate electrode structure (not shown). In some embodiments, the change in work function from an undoped gate electrode structure (not shown) to the work function of the gate electrode structure 105 with a doped region 308 is between approximately ±10%. For example, if the gate material layer 102 is made of polycrystalline tungsten (with a work function of 4.55 eV), the first interfacial layer 106 is made of aluminum oxide, and the insulator 108 is made of silicon oxide, the other parameters may be altered such that the work function of the undoped gate electrode structure (not shown) would be at 5 eV, approximately 10% higher than the work function of the gate material layer 102. With the inclusion of a doped region 308 within the active layer 110, the work function of the gate electrode structure 105 may be raised by approximately 10% more, to 5.5 eV. Greater or lower changes in the work function of the gate electrode structure 105 may be possible by altering the distribution, concentration, and type of dopants implanted in the first interfacial layer 106.

Also shown in the cross-sectional view 300a of FIG. 3A is that in some embodiments, the source/drain structures 114 may be surrounded by a barrier layer 310. The barrier layer 310 separates the source/drain structures 114 from the dielectric layer 112 and the active layer 110. When the source/drain structures 114 are made of a metal such as copper, the barrier layer 310 may mitigate the diffusion of the metal through the dielectric layer 112 and the active layer 110.

As shown in the cross-sectional view 300b of FIG. 3B, the thin film transistor may have a second interfacial layer 312 between the first interfacial layer 106 and the insulator 108. The second interfacial layer 312 may comprise a different material than the first interfacial layer 106, and may have a third oxygen areal density different than the second oxygen areal density of the first interfacial layer 106. The difference between the third oxygen areal density and the second oxygen areal density may be greater than the difference between the second oxygen areal density and the first oxygen areal density. The greater difference in oxygen areal density may lead to a higher dipole moment at the interface between the first interfacial layer 106 and the second interfacial layer 312, causing an increased change in work function. In some embodiments, a second dipole is formed between the second interfacial layer 312 and the insulator 108. The dipole formed between the first interfacial layer 106 and the second interfacial layer 312 has a significantly greater effect on the change in work function than the second dipole.

In some embodiments, the first interfacial layer 106 may comprise a material from either a first subset or a second subset of materials. In further embodiments, the second interfacial layer 312 may comprise a material from a subset different from the subset of the material of the first interfacial layer 106. For example, a first subset of materials may comprise aluminum oxide (Al₂O₃), zinc oxide (ZnO), indium oxide (In₂O₃), gallium oxide (GaO), tungsten oxide (W₂O₃), and the like, while the second subset of materials may comprise hafnium oxide (HfO), zirconium oxide (ZrO), lanthanum oxide (La₂O₃), silicon oxide (SiO₂), yttrium oxide (Y₂O₃), tantalum oxide (Ta₂O₅), and the like. In this example, if a first interfacial layer 106 comprises a material from the first subset (e.g., aluminum oxide), the second interfacial layer 312 must comprise a material from the second subset (e.g., hafnium oxide). Depending on the materials of the gate material layer 102, the first interfacial layer 106, the second interfacial layer 312, and the insulator 108 that are chosen, the gate electrode structure 105 may exhibit a work function that is less than, greater than, or in between the work functions of the individual layers that comprise it. The thin film transistor with more than one interfacial layer, in turn, may tune the threshold voltage of the resulting device with a greater range and accuracy than a thin film transistor with a single interfacial layer. In some embodiments, the thin film transistor may have two or more interfacial layers.

For example, if the gate material layer 102 is made of polycrystalline tungsten (with a work function of 4.55 eV), the first interfacial layer 106 is made of aluminum oxide, and the insulator 108 is made of silicon oxide, the other parameters may be altered such that the work function of the gate electrode structure 105 would be at 4.77 eV, approximately 5% higher than the work function of the gate material layer 102. With the inclusion of a second interfacial layer 312 made of lanthanum oxide (with an oxygen areal density lower than silicon oxide), the work function of the gate electrode structure 105 may be raised by approximately 5% more, to 5 eV, due to the greater difference in oxygen areal density between the first and second interfacial layer 106, 312. The inclusion of the second interfacial layer 312 may also change the direction of the dipole dominating the change in work function. A greater or lesser variance from the work function of the gate material layer 102 can be achieved by altering the thickness t3, t2 and materials of the first interfacial layer 106 and the insulator 108, as well as a thickness and material of the second interfacial layer 312. Greater or lower changes in the work function of the gate electrode structure 105 may be possible by altering the distribution, concentration, and type of dopants implanted in the first interfacial layer 106.

In some embodiments, both or either of the first interfacial layer 106 and the second interfacial layer 312 may additionally have a doped region (e.g., the doped region 308 of FIG. 3A). The addition of a doped region (e.g., the doped region 308 of FIG. 3A) in one or both of the first interfacial layer 106 and the second interfacial layer 312 may offer additional methods to alter the work function of the resultant gate electrode structure 105, further increasing possible range and specificity of the work function and resulting threshold voltage. Additionally, the possibility of using each of these methods in tandem increases the flexibility in which processes can accommodate this method of threshold voltage tuning, as these steps may be incorporated into other processes used in device manufacture.

As shown in the cross-sectional views 300c of FIG. 3C, a TG device may have a doped region 308 within the first interfacial layer 106 that is the result of a treatment process where dopants 302 are implanted near a first surface 304 of the first interfacial layer 106. The doped region 308 of the TG device and surface treatment performed is identical to those described in relation to the thin film transistor of FIG. 3A, except for as described hereafter. In some embodiments, as shown in FIG. 3C, the first surface 304 of the first interfacial layer 106 is facing toward the gate material layer 102, and the doped region 308 is spaced from the insulator 108.

As shown in the cross-sectional views 300d of FIG. 3D, a TG device may have a doped region 308 within the first interfacial layer 106 that is the result of a treatment process where dopants 302 are implanted near a first surface 304 of the first interfacial layer 106. The doped region 308 of the TG device and surface treatment performed is identical to those described in relation to the thin film transistor of FIG. 3A, except for as described hereafter. In other embodiments, as shown in FIG. 3D, the first surface 304 of the first interfacial layer 106 is beneath the second surface 306, and the doped region 308 is spaced from the exposed second surface 306 of the first interfacial layer 106. In further embodiments, the doped region 308 is formed beneath the exposed second surface 306 using a deep implant process, thereby forming the doped region 308 closer to the insulator 108 than the gate material layer 102. In other embodiments, the doped region 308 is formed by performing the surface treatment on a thin interfacial starter layer (not shown) and then depositing an untreated interfacial layer (not shown), the thin interfacial starter layer and the untreated interfacial layer together forming the first interfacial layer 106 with the doped region 308 near the insulator 108.

As shown in the cross-sectional view 300e of FIG. 3E, a TG device may have a second interfacial layer 312 between the first interfacial layer 106 and the gate material layer 102. The second interfacial layer 312 of the TG device is identical to that described in relation to the thin film transistor of FIG. 3B, except the second interfacial layer 312 of the TG device is between the gate material layer 102 and the first interfacial layer 106, and the second dipole is formed between the first interfacial layer 106 and the insulator 108.

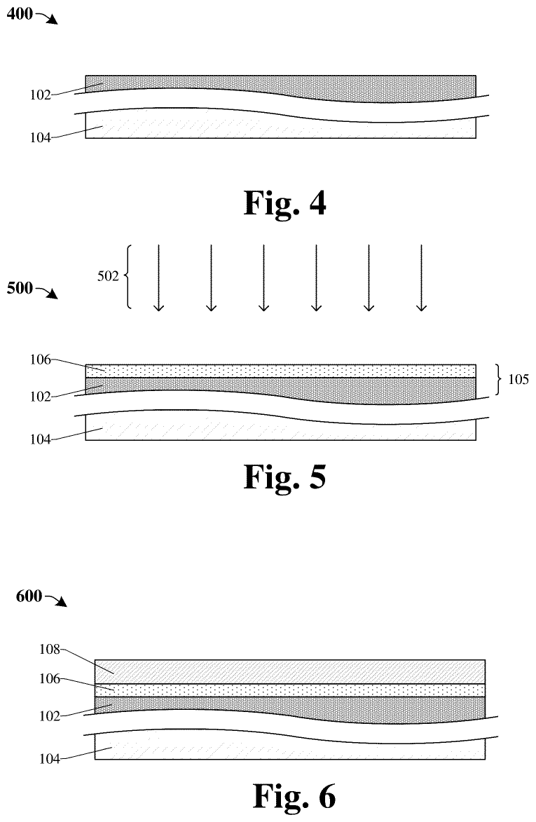

With reference to FIGS. 4 through 10, cross-sectional views 400-1000 of some embodiments of a BG thin film transistor device including an interfacial layer at various stages of manufacture are provided. Although FIGS. 4 through 10 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 400 of FIG. 4, a gate material layer 102 is formed over a substrate 104. In some embodiments, the gate material layer 102 may be formed using a deposition process such as, for example, chemical vapor deposition (CVD), physical vapor deposition (PVD), some other suitable deposition process(es), or any combination of the foregoing to form an un-patterned gate layer (not shown). Portions of the un-patterned gate layer are then removed, leaving the gate material layer 102 positioned over the substrate 104. The portions of the un-patterned gate layer are removed by exposing the portions to one or more etchants. The etching process, for example, may be performed by a photolithography/etching process and/or some other suitable patterning process(es). In some embodiments, the gate material layer 102 may comprise one of copper (Cu), tungsten (W), aluminum (Al), titanium (Ti), tantalum (Ta), or some other suitable conductive material. In some embodiments, the gate material layer 102 is separated from the substrate 104 by an interconnect structure 103 containing one or more circuit elements. In other embodiments, the gate material layer 102 is contacting the substrate 104.

As shown in the cross-sectional view 500 of FIG. 5, a first interfacial layer 106 is deposited over the gate material layer 102, forming a gate electrode structure 105. In some embodiments, the interfacial layer may be formed using a deposition process 502 such as, for example, chemical vapor deposition (CVD), physical vapor deposition (PVD), some other suitable deposition process(es), or any combination of the foregoing. The thickness t3 of the first interfacial layer 106 formed is determined based on the desired threshold voltage derived from the work function of the gate electrode structure 105. In some embodiments, the first interfacial layer 106 may comprise one of zinc oxide (ZnO), aluminum oxide (Al₂O₃), indium oxide (In₂O₃), hafnium oxide (HfO), zirconium oxide (ZrO), gallium oxide (GaO), lanthanum oxide (La₂O₃), silicon dioxide (SiO₂), yttrium oxide (Y₂O₃), tantalum oxide (Ta₂O₅). In some embodiments, the first interfacial layer 106 is confined above outer sidewalls of the gate material layer 102. In other embodiments, the first interfacial layer 106 surrounds outer sidewalls of the gate material layer 102.

As shown in the cross-sectional view 600 of FIG. 6, an insulator 108 is formed over the first interfacial layer 106. In some embodiments, the insulator 108 may be formed using a deposition process such as, for example, chemical vapor deposition (CVD), physical vapor deposition (PVD), some other suitable deposition process(es), or any combination of the foregoing. In some embodiments, the insulator 108 may comprise one of silicon oxide (SiOx), aluminum oxide (AlOx), hafnium oxide and zirconium oxide (HfOx:ZrOx), hafnium oxide and aluminum oxide (HfOx:AlOx); hafnium oxide and lanthanum oxide (HfOx:LaOx), hafnium oxide and silicon oxide (HfOx:SiOx), hafnium oxide and strontium oxide (HfOx:SrO), or HZO doped cerium oxide (CeOx). In some embodiments, the insulator 108 is confined between outer sidewalls of the first interfacial layer 106. In other embodiments, the insulator 108 surrounds outer sidewalls of the first interfacial layer 106.

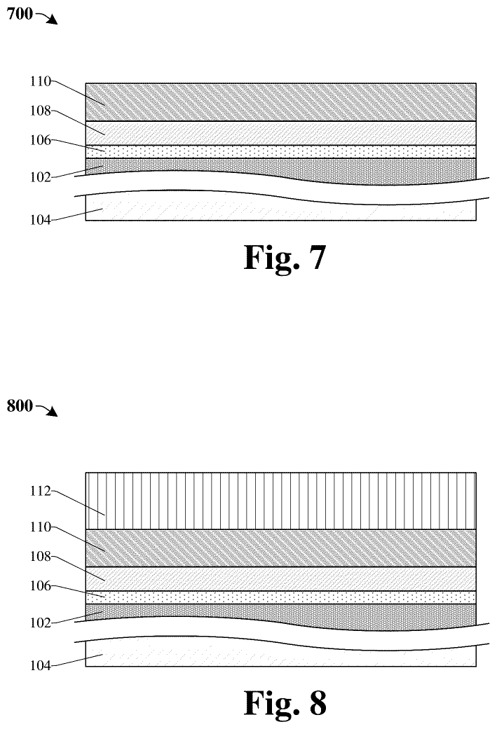

As shown in the cross-sectional view 700 of FIG. 7, an active layer 110 is formed over the insulator 108. In some embodiments, the active layer 110 may be formed using a deposition process such as, for example, chemical vapor deposition (CVD), physical vapor deposition (PVD), some other suitable deposition process(es), or any combination of the foregoing. In some embodiments, the active layer 110 may comprise one of silicon (Si), polysilicon (poly-Si) or a metal oxide film such as indium zinc oxide (IZO); indium gallium oxide (IGO); indium gallium zinc oxide (IGZO); indium tungsten oxide (IWO); or indium tungsten zinc oxide (IWZO). In some embodiments, the active layer 110 is confined between outer sidewalls of the insulator 108. In other embodiments, the active layer 110 surrounds outer sidewalls of the insulator 108.

As shown in the cross-section view 800 of FIG. 8, a dielectric layer 112 is formed over the active layer 110. In some embodiments, the dielectric layer 112 may be formed using a deposition process such as, for example, chemical vapor deposition (CVD), physical vapor deposition (PVD), some other suitable deposition process(es), or any combination of the foregoing. In some embodiments, the dielectric layer 112 may comprise one of a nitride (e.g., silicon nitride, silicon oxynitride), a carbide (e.g., silicon carbide), an oxide (e.g., silicon oxide), borosilicate glass (BSG), phosphoric silicate glass (PSG), borophosphosilicate glass (BPSG), a low-k oxide (e.g., a carbon doped oxide, SiCOH), or the like. In some embodiments, the active layer 110 is confined between outer sidewalls of the insulator 108. In other embodiments, the active layer 110 surrounds outer sidewalls of the insulator 108.

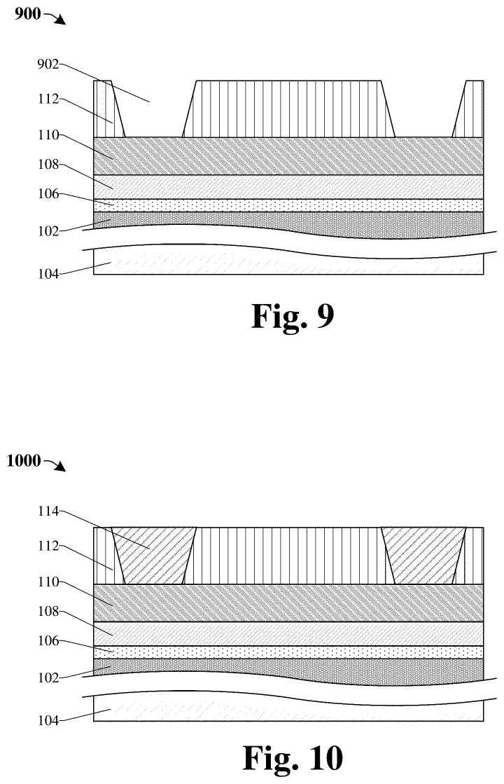

As shown in the cross-section view 900 of FIG. 9, source/drain openings 902 are formed in the dielectric layer 112. In some embodiments, the source/drain openings 902 extend to a top surface of the active layer 110, where a portion of the active layer 110 between the source/drain openings 902 is the channel of the transistor. The source/drain openings 902 are formed by an etching process that includes exposing the dielectric layer 112 to one or more etchants. The etching process, for example, may be performed by a photolithography/etching process and/or some other suitable patterning process(es).

As shown in the cross-sectional view 1000 of FIG. 10, source/drain structures 114 are formed within the source/drain openings (not shown) (see FIG. 9). In some embodiments, the source/drain structures 114 may be formed using a deposition process such as, for example, chemical vapor deposition (CVD), physical vapor deposition (PVD), some other suitable deposition process(es), or any combination of the foregoing to fill the source/drain openings with a conductive material, and then using a planarization process (e.g., chemical mechanical planarization) to remove portions of the conductive material outside of the source/drain openings. In some embodiments, the source/drain structures 114 may comprise one of copper (Cu), tungsten (W), aluminum (Al), titanium (Ti), tantalum (Ta), or some other suitable conductive material.

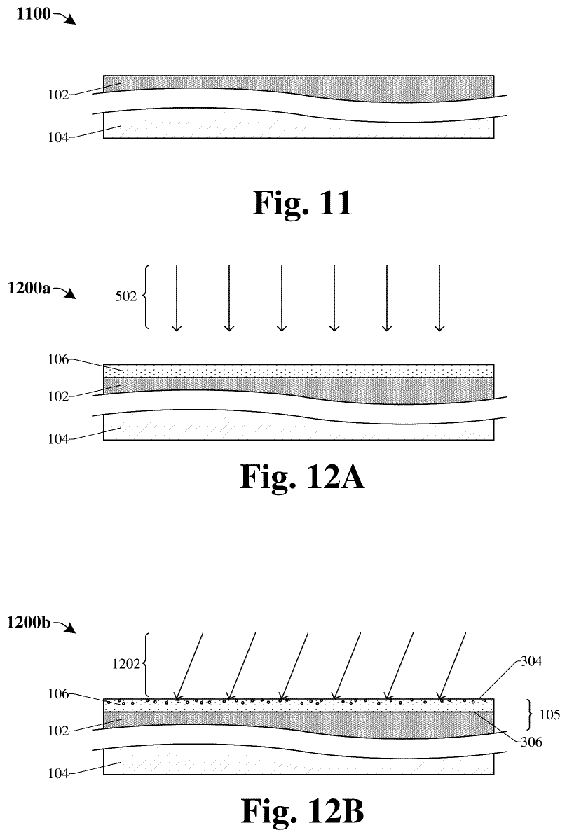

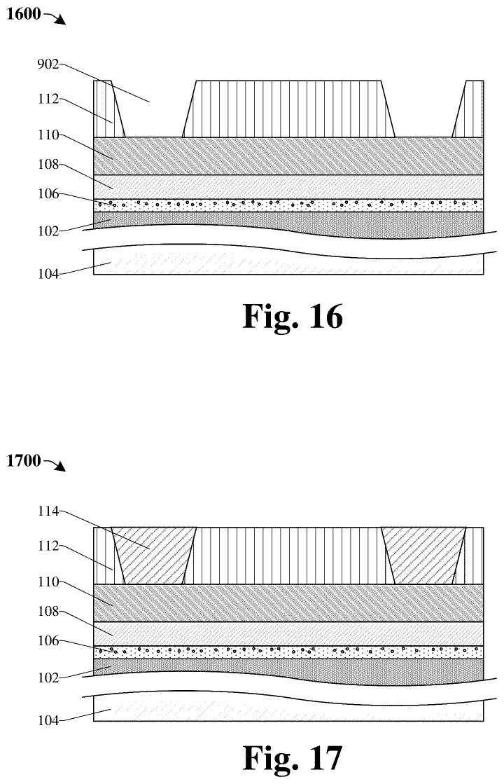

FIGS. 11-17 illustrate cross-sectional views 1100-1700 of some embodiments of a BG thin film transistor device including an interfacial layer with a treated surface at various stages of manufacture. Compared to FIGS. 4-10, the embodiments of FIGS. 11-17 include performing a surface treatment 1202 on the first interfacial layer 106 after it is formed. This inclusion may further alter the work function of the gate electrode structure 105, allowing an additional process by which the work function and threshold voltage of the resulting device may be tuned.

More particularly, as shown in cross-sectional view 1100 of FIG. 11, a gate material layer 102 is formed over a substrate 104. The gate material layer 102 is formed in a manner identical to that described in relation to FIG. 4.

As shown in the cross-sectional view 1200a of FIG. 12A, a first interfacial layer 106 is formed. The interfacial layer is formed in a manner identical to that described in relation to FIG. 5.

As shown in the cross-sectional view 1200b if FIG. 12B, a surface treatment 1202 is performed on the interfacial layer. The surface treatment 1202 is performed at a temperature approximately between 250 and 400 degrees Celsius, approximately between 200 and 300 degrees Celsius, approximately between 350 and 500 degrees Celsius, or within another similar range. In some embodiments, the surface treatment is performed in one or more steps that individually comprise exposing the first interfacial layer 106 to one of a hydrogen plasma, an oxygen plasma, a nitrogen plasma, a combination of the listed plasmas, or the like. In some embodiments, the surface treatment is a combination of a hydrogen treatment, an oxygen treatment, and a nitrogen treatment. In further embodiments, the treatments are performed consecutively in situ. The duration of the surface treatment 1202 is between approximately 10 and 60 seconds, between approximately 5 and 30 seconds, between approximately 40 and 80 seconds, or is within another similar range.

The surface treatment 1202 results in an implantation of dopants into an exposed surface of the first interfacial layer 106. In some embodiments, there is a greater concentration of dopants near a first surface 304 of the first interfacial layer 106 exposed to the surface treatment 1202 than are near a second surface 306 of the first interfacial layer 106. In some embodiments, the dopants implanted are one of hydrogen, oxygen, nitrogen, a combination of hydrogen and oxygen, or the like. In some embodiments, the surface treatment comprises performing a hydrogen or nitrogen surface treatment to implant hydrogen or oxygen into the exposed surface of the first interfacial layer 106, and then performing a nitrogen surface treatment to remove or recover a portion of the hydrogen or oxygen implanted in the first interfacial layer 106. This combination of steps offers finer control over the final number of implanted dopants in the first interfacial layer 106, changing the first oxygen areal density.

In some embodiments, the surface treatment 1202 alters the crystal structure of the exposed surface of the first interfacial layer 106. In some embodiments, the surface treatment 1202 results in stronger bonds between the first interfacial layer 106 and the insulator 108 to be added hereafter.

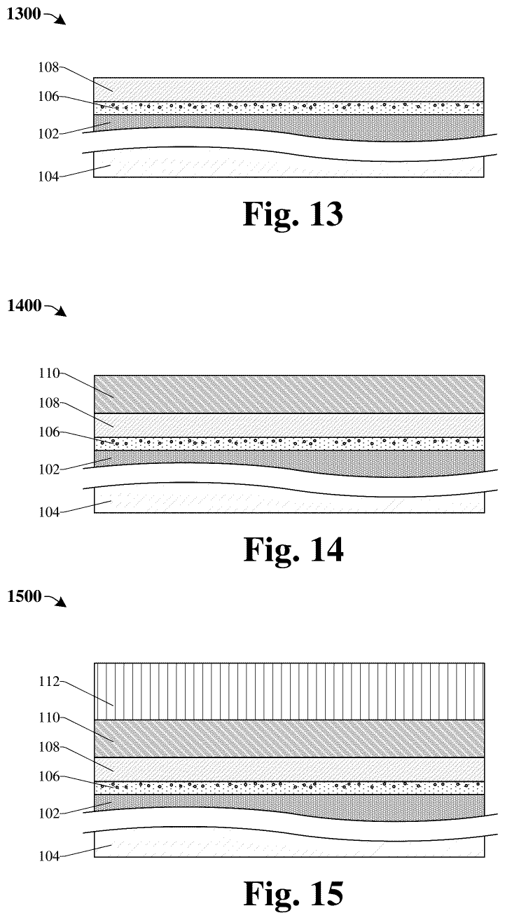

As shown in the cross-sectional views 1300-1700 of FIGS. 13-17, an insulator 108, an active layer 110, a dielectric layer 112, and source/drain structures 114 are formed. The insulator 108, the active layer 110, the dielectric layer 112, and the source/drain structures are formed in a manner identical to that described in relation to FIGS. 6-10.

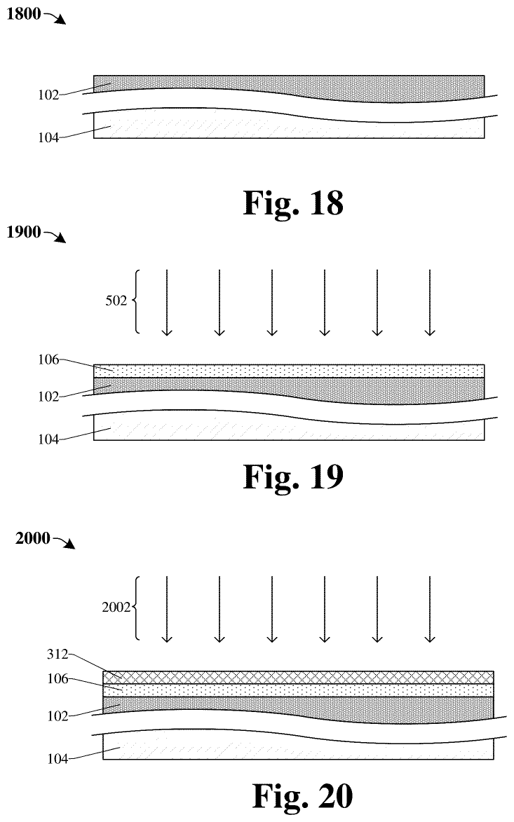

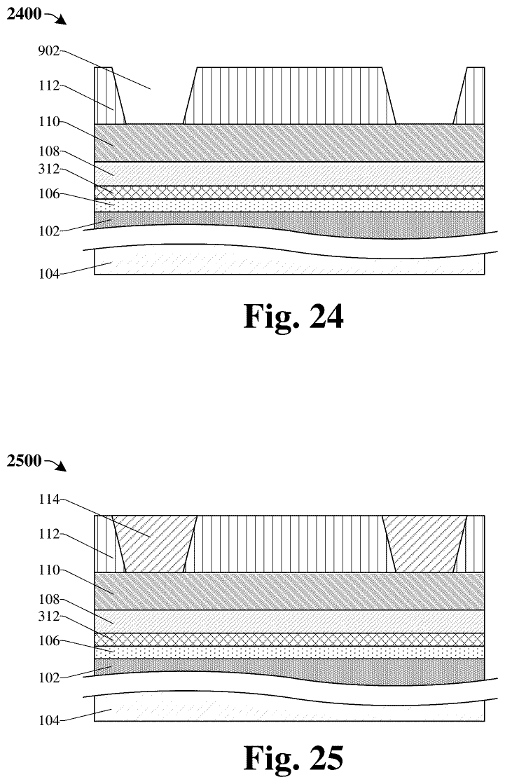

FIGS. 18-25 illustrate an alternative set cross-sectional views 1800-2500 of some embodiments of a BG thin film transistor device including a first interfacial layer and a second interfacial layer at various stages of manufacture. Compared to FIGS. 4-10, the embodiments of FIGS. 18-25 include forming a second interfacial layer 312 over the first interfacial layer 106. This inclusion may further alter the work function of the gate electrode structure 105, allowing an additional process by which the work function and threshold voltage of the resulting device may be tuned.

More particularly, as shown in cross-sectional view 1800 of FIG. 18, a gate material layer 102 is formed over a substrate 104. The gate material layer 102 is formed in a manner identical to that described in relation to FIG. 4.

As shown in the cross-sectional view 1900 of FIG. 19, a first interfacial layer 106 is formed. The first interfacial layer 106 may comprises a material that is part of a first subset or a second subset of interfacial layer materials. The first subset comprises aluminum oxide (Al₂O₃), zinc oxide (ZnO), indium oxide (In₂O₃), gallium oxide (GaO), tungsten oxide (W₂O₃), and the like. The second subset comprises hafnium oxide (HfO), zirconium oxide (ZrO), lanthanum oxide (La₂O₃), silicon oxide (SiO₂), yttrium oxide (Y₂O₃), tantalum oxide (Ta₂O₅), and the like. Beyond the material of the first interfacial layer 106, the first interfacial layer 106 is formed in a similar manner as illustrated in FIG. 5.

As shown in the cross-sectional view 2000 if FIG. 20, a second interfacial layer 312 is formed. In some embodiments, the interfacial layer may be formed using a deposition process 2002 such as, for example, chemical vapor deposition (CVD), physical vapor deposition (PVD), some other suitable deposition process(es), or any combination of the foregoing. The thickness of the second interfacial layer 312 formed may be set based on a desired threshold voltage derived from the combined work function of the gate electrode structure 105. The second interfacial layer 312 comprises a material that is part of a first subset or a second subset of interfacial layer materials that is different from the subset of the material chosen for the first interfacial layer 106. For example, if the first interfacial layer 106 comprises aluminum oxide (Al₂O₃), the second interfacial layer 312 may comprise any material from the second subset, such as hafnium oxide (HfO). The first interfacial layer 106 and the second interfacial layer 312 form a dipole that alters the work function of the gate electrode structure 105. In some embodiments, the dipole formed between the first interfacial layer 106 and the second interfacial layer 312 increases the work function of the gate electrode structure 105 more than a dipole between the insulator 108 and the first interfacial layer 106 would individually. In other embodiments, the dipole formed between the first interfacial layer 106 and the second interfacial layer 312 results in a work function lower than the work function of the gate electrode structure 105 without the second interfacial layer 312 being added. The combination of the first interfacial layer 106 and the second interfacial layer 312 offers an additional method of tuning the threshold voltage by increasing or decreasing the work function of the device.

In some embodiments, a surface treatment (not shown) similar to that described in relation to FIG. 12B is performed before and/or after the process described in relation to FIG. 20. That is, in some embodiments, the surface treatment 1202 (see FIG. 12B) may be performed on the first interfacial layer 106 as described in relation to FIG. 12B before the second interfacial layer 312 is formed. In some embodiments, an additional surface treatment identical to that described in relation to FIG. 12B may be performed on the second interfacial layer 312. That is, in some embodiments, one or both of the first interfacial layer 106 and the second interfacial layer 312 may undergo a surface treatment identical to the surface treatment 1202 (see FIG. 12B). The inclusion of a surface treatment into the process of forming the semiconductor device offers an additional method of tuning the threshold voltage by increasing or decreasing the work function of the resultant device.

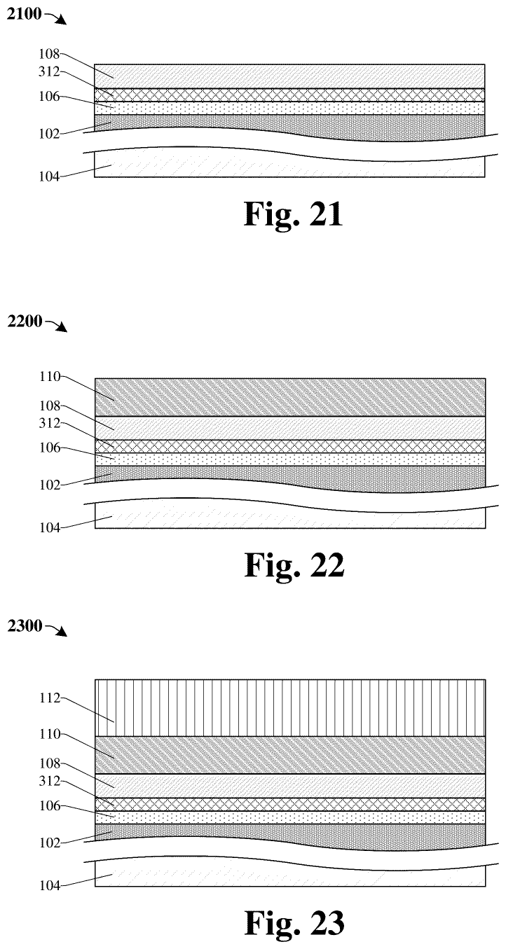

As shown in the cross-sectional views 2100-2500 of FIGS. 21-25, an insulator 108, an active layer 110, a dielectric layer 112, and source/drain structures 114 are formed. The insulator 108, the active layer 110, the dielectric layer 112, and the source/drain structures are formed in a manner identical to that described in relation to FIGS. 6-10.

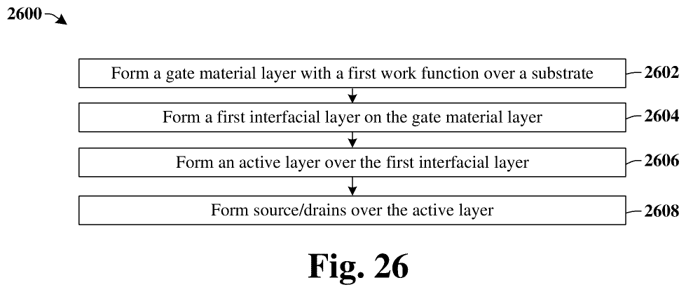

FIG. 26 illustrates a method 2600 of forming a memory device in accordance with some embodiments. Although the method 2600 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2602, a gate is formed over a substrate with a first work function. FIG. 4 illustrates a cross-sectional view 400 corresponding to some embodiments of act 2602.

At 2604, a first interfacial layer with a second work function different from the first work function is formed over the gate. FIG. 5 illustrates a cross-sectional view 500 corresponding to some embodiments of act 2604.

At 2606, an active layer is formed over the first interfacial layer. FIG. 7 illustrates a cross-sectional view 700 corresponding to some embodiments of act 2606.

At 2608, source/drain structures are formed over the active layer. FIGS. 9-10 illustrate cross-sectional views 900-1000 corresponding to some embodiments of act 2608.

Accordingly, in some embodiments, the present disclosure relates to a method of forming a transistor including an interfacial layer designed to alter the work function of a gate electrode in order to tune the threshold voltage of the transistor while eliminating ion degradation and damage to the active layer due to ion implantation.

Some embodiments relate to a thin film transistor comprising an active layer over a substrate. An insulator is stacked with the active layer. A gate electrode structure is stacked with the insulator and includes a gate material layer having a first work function and a first interfacial layer. The first interfacial layer is directly between the insulator and the gate material layer, wherein the gate electrode structure has a second work function that is different from the first work function.

Other embodiments relate to an integrated chip. The integrated chip includes a substrate and a thin film transistor disposed over the substrate. The thin film transistor includes an active layer and a gate material layer stacked with the active layer, the gate material layer having a first work function. The thin film transistor further includes a first interfacial layer disposed between the active layer and the gate material layer. A second interfacial layer is contacting the first interfacial layer. The thin film transistor is configured to have a threshold voltage based on a second work function of a gate electrode structure containing the gate material layer, first interfacial layer, and the second interfacial layer.

Yet other embodiments relate to a method of forming a thin film transistor, the method including forming a gate material layer with a first work function over a substrate. A first interfacial layer is formed on the gate material layer. An insulator is formed on the first interfacial layer. An active layer is then formed on the first interfacial layer.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thin film transistor, comprising:
an active layer over a substrate;
an insulator stacked with the active layer;
a gate electrode structure stacked with the insulator, wherein the gate electrode structure comprises:
a gate material layer having a first work function; and
a first interfacial layer directly between the insulator and the gate material layer, wherein the gate electrode structure has a second work function different from the first work function.

2. The thin film transistor of claim 1, wherein the first interfacial layer has a first surface facing the insulator and a second surface facing the gate material layer, wherein the first interfacial layer comprises a doped region disposed along the first surface and vertically offset the second surface, wherein the doped region is configured to alter the second work function of the gate electrode structure.

3. The thin film transistor of claim 1, wherein the insulator has a first oxygen areal density, and wherein the first interfacial layer has a second oxygen areal density different from the first oxygen areal density.

4. The thin film transistor of claim 3, wherein the gate electrode structure further comprises a second interfacial layer directly between the insulator and the first interfacial layer, wherein the second interfacial layer has a third oxygen areal density that is different from the second oxygen areal density.

5. The thin film transistor of claim 1, wherein the gate electrode structure further comprises a second interfacial layer directly between the insulator and the first interfacial layer, wherein the second interfacial layer decreases the second work function of the gate electrode structure.

6. The thin film transistor of claim 1, wherein the gate material layer is directly beneath the first interfacial layer and separates the substrate from the first interfacial layer.

7. An integrated chip, comprising:
a substrate;
a thin film transistor disposed over the substrate, wherein the thin film transistor comprises:
an active layer;
a gate material layer stacked with the active layer, wherein the gate material layer has a first work function;
a first interfacial layer disposed between the active layer and the gate material layer; and
a second interfacial layer contacting the first interfacial layer, wherein the thin film transistor is configured to have a threshold voltage based on a second work function of a gate electrode structure comprising the gate material layer, the first interfacial layer, and the second interfacial layer.

8. The integrated chip of claim 7, wherein the second work function is less than the first work function.

9. The integrated chip of claim 7, wherein a dipole is formed at an interface between the first interfacial layer and the second interfacial layer, wherein the dipole raises the second work function of the gate electrode structure.

10. The integrated chip of claim 7, wherein the first interfacial layer comprises aluminum oxide (Al₂O₃) and the second interfacial layer comprises zirconium oxide (ZrO).

11. The integrated chip of claim 7, wherein the first interfacial layer has a first oxygen areal density, and wherein the second interfacial layer has a second oxygen areal density that is greater than the first oxygen areal density.

12. The integrated chip of claim 7, wherein the first interfacial layer has a first oxygen areal density, and wherein the second interfacial layer has a second oxygen areal density that is less than the first oxygen areal density.

13. A method of forming a thin film transistor, comprising:
forming a gate material layer with a first work function over a substrate;
forming a first interfacial layer on the gate material layer;
forming an insulator on the first interfacial layer; and
forming an active layer on the first interfacial layer.

14. The method of claim 13, further comprising:
performing a surface treatment on a first surface of the first interfacial layer, wherein the surface treatment increases a second work function of a gate electrode structure comprising the gate material layer and the first interfacial layer.

15. The method of claim 14, wherein the first interfacial layer has a first oxygen areal density and the insulator has a second oxygen areal density different from the first oxygen areal density.

16. The method of claim 14, wherein the surface treatment comprises a hydrogen treatment, an oxygen treatment, and a nitrogen treatment, each performed consecutively in situ.

17. The method of claim 14, further comprising:
depositing a second interfacial layer on the first interfacial layer, thereby forming a dipole between the first interfacial layer and the second interfacial layer.

18. The method of claim 17, wherein the second interfacial layer increases the second work function of the gate electrode structure.

19. The method of claim 17, wherein the first interfacial layer comprises a first material and the second interfacial layer comprises a second material, wherein the first material comprises one of aluminum oxide (Al₂O₃), zinc oxide (ZnO), indium oxide (In₂O₃), gallium oxide (GaO), or tungsten oxide (W₂O₃), and wherein the second material comprises one of hafnium oxide (HfO), zirconium oxide (ZrO), lanthanum oxide (La₂O₃), silicon oxide (SiO₂), yttrium oxide (Y₂O₃), or tantalum oxide (Ta₂O₅).

20. The method of claim 13, wherein a gate electrode structure comprising the gate material layer and the first interfacial layer has a second work function different from the first work function.
